(19) United States
(12) Patent Application Publication
(10) Pub. No.: US 2014/0270731 A1
(43) Pub. Date: Sep. 18, 2014

(54) THERMAL MANAGEMENT APPARATUS FOR SOLID STATE LIGHT SOURCE ARRAYS

(71) Applicant: APPLIED MATERIALS, INC., Santa Clara, CA (US)

(72) Inventors: JOHN GERLING, Lafayette, CA (US); JOSEPH M. RANISH, San Jose, CA (US)

(73) Assignee: APPLIED MATERIALS, INC., Santa Clara, CA (US)

(21) Appl. No.: 14/182,858

(22) Filed: Feb. 18, 2014

Related U.S. Application Data
(60) Provisional application No. 61/777,521, filed on Mar. 12, 2013.

(51) Int. Cl. H01L 21/02

(52) U.S. Cl. CPC H01L 21/02
USPC 392/408; 392/416

(57) ABSTRACT

Apparatus for providing pulsed or continuous energy in a process chamber are provided herein. The apparatus may include a process chamber comprising a chamber body, a solid state light source array, having a plurality of solid state light sources disposed on a first substrate, to provide pulsed or continuous energy to the process chamber, and a cooling mechanism including a band pass filter to reduce an amount of reflected light from heating the solid state source array.

### CROSS-REFERENCE TO RELATED APPLICATIONS

This application claims benefit of U.S. provisional patent application Ser. No. 61/777,521, filed Mar. 12, 2013, which is herein incorporated by reference.

### FIELD

Embodiments of the present invention generally relate to semiconductor processing systems and, more specifically, to solid state light sources for use in semiconductor processing systems.

### FIELD

Embodiments of the present invention generally relate to semiconductor processing systems and, more specifically, to solid state light sources for use in semiconductor processing systems.

### BACKGROUND

Several applications that involve the thermal processing of substrates such as semiconductor wafers and other materials involve the process steps of rapidly heating and cooling a substrate. Examples of such processing include rapid thermal processing (RTP), physical vapor deposition (PVD) processing, and the like, which are used for a number of semiconductor fabrication processes.

During semiconductor fabrication processing, heat energy from lamps is radiated into the process chamber and onto a semiconductor substrate in the processing chamber. In this manner, the substrate is heated to a required processing temperature. Typically, the use of conventional lamps (tungsten-halogen, mercury vapor, arc discharge) or electrical heating elements has been the dominant approach to delivering energy to the substrate for dopant annealing, film deposition, or film modification. These processes are often thermally based and typically require high process temperatures ranging from 200 C to 1600 C, which can result in significant thermal budget issues that adversely affect device performance. In addition, the use of conventional lamps has associated high maintenance costs with respect to operating lifetime, material and energy usage. Conventional lamps emit radiation over a broad spectrum of wavelengths which can be detrimental to some instrumentation and/or result in an unintended response in the target substrate/film from the undesired wavelengths.

Arrays of solid state light sources, for example Light Emitting Diodes (LEDs), may be used instead of, or in addition to, conventional lamps for various semiconductor fabrication processes to address some of the foregoing issues. In order to achieve target irradiance levels on the order of 1e6 W/m̂2 that are comparable to the intensities required for RTP, high packing density of LEDs would need to be used.

However, heat dissipation and thermal management is important to the operation of ultra high intensity LED arrays. These LED arrays should remain at or near room temperature in order to extract the maximum brightness and long operating lifetime. There are many approaches to solving the heat dissipation issue, such as cold plates, heat pipes, or Peltier coolers. However, none of these solutions sufficiently addresses the heat dissipation requirements associated with LED arrays.

Specifically, cold plates are typically only good for 1 kW dissipation with 20 K rise in temperature. They can be designed for large area but for high power densities this is not enough. Heat pipes have thermal conductivities of 5,000 W/m/K to 200,000 W/m/K. They are effective in transporting heat from one point to another, but not in removing the heat from a system, where a heat sink is required. Finally, thermoelectric coolers (aka Peltier coolers) are capable of approx 1e5 W/m̂2 cooling but only available in small sizes. They are costly and require as much power input to operate as the electronics to be cooled.

Accordingly, the inventors have provided improved heat dissipation and thermal management devices for use with solid state light source array for use in semiconductor processing systems.

### SUMMARY

Apparatus for providing pulsed or continuous energy in a process chamber are provided herein. The apparatus may include a process chamber comprising a chamber body, a solid state light source array, having a plurality of solid state light sources disposed on a first substrate, to provide pulsed or continuous energy to the process chamber, and a cooling mechanism including a band pass filter to reduce an amount of reflected light from heating the solid state source array.

In some embodiments, an apparatus for providing pulsed or continuous energy in a process chamber may include a process chamber comprising a chamber body, a solid state light source array, having a plurality of solid state light sources, disposed on a first substrate, to provide pulsed or continuous energy to the process chamber, and a cooling mechanism including a transparent window disposed over the solid state light source array forming a cooling channel disposed between the plurality of solid state light sources and the window configured to flow the coolant over the plurality of solid state light sources.

In some embodiments, an apparatus for providing pulsed or continuous energy in a process chamber comprising a chamber body, a solid state light source array, having a plurality of solid state light sources, disposed on a first surface of a substrate, to provide pulsed or continuous energy to the process chamber, and a cooling mechanism coupled to a second surface of the substrate to remove heat from the solid state light source array, the cooling mechanism including a base plate, a top plate, and a plurality of fins disposed between the base plate and the top plate.

Other embodiments and variations of the present invention are disclosed in greater detail below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a schematic, cross-sectional view of a semiconductor substrate process chamber in accordance with some embodiments of the present invention;

FIG. 2 is a top view of an solid state light source that includes a plurality of LED arrays in accordance with some embodiments of the present invention;

FIG. 3 is a schematic top view of a circular cross section LED array in accordance with some embodiments of the present invention; and

FIG. 4 is a schematic cross sectional side view of a cooling mechanism including a band pass filter in accordance with some embodiments of the present invention;

FIGS. 5A and 5B are schematic cross sectional side views of a cooling mechanism including immersion cooling in accordance with some embodiments of the present invention;

FIG. 6 is an isometric view a cooling mechanism including non-immersion cooling in accordance with some embodiments of the present invention; and

FIGS. 7A-7C includes schematic cross sectional side views for different embodiments of fins that could be used in a cooling mechanism in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of an apparatus for providing pulsed or continuous energy in a process chamber are provided herein. In some embodiments, the inventive apparatus may advantageously provide improved cooling and thermal management of solid state light sources used in process chambers for heating of substrates and other components disposed in a process chamber.

In the following description, the term substrate is intended to broadly cover any object that is being processed in a thermal process chamber. The term substrate may include, for example, semiconductor wafers, flat panel displays, glass plates or disks, plastic workpieces, and the like. In the following description solid state light point sources include light emitting diodes (LEDs) and LASERs. In addition, although described below in terms of LEDs or arrays of LEDs, LASERs and arrays of LASERs, other solid state light point sources may be used interchangeably in embodiments described herein.

FIG. 1 depicts a schematic of an exemplary process chamber 100 configured to perform thermal processes, such as a rapid thermal process (RTP), and suitable for use with the inventive LED source for heating substrates in accordance with some embodiments of the present invention. The process chamber 100 may be any type of process chamber having a substrate support configured to support a substrate (e.g., process chamber that includes a substrate support ring, a susceptor which holds the substrate in multiple places, air jets that holds the substrate in place) and having a reflector plate located along a back side of the substrate. Examples of suitable process chambers includes any of the RADIANCE®, RADIANCE® PLUS, or VANTAGE® process chambers, or any other process chamber capable of performing a thermal process, for example RTP, all available from Applied Materials, Inc., of Santa Clara, Calif. Other suitable process chambers, including those available from other manufacturers may also be used and/or modified in accordance with the teachings provided herein. For example, other suitable process chambers that may utilize the inventive LED source for heating substrates described herein include Physical Vapor Deposition (PVD) chambers, Chemical Vapor Deposition (CVD) chambers, Epitaxial Deposition chambers, etch chambers, Atomic Layer Deposition (ALD) chambers, etc.

The process chamber 100 may, for example, be adapted for performing thermal processes and illustratively comprises a chamber body 110, support systems 130, and a controller 140 that includes of a CPU 142, memory 144, and support circuits 146. The process chamber 100 depicted in FIG. 1 is illustrative only and other process chambers, including those configured for processes other than RTP, may be modified in accordance with the teachings provided herein.

The process chamber 100 includes a energy source 138, which may include a plurality of LEDs or array(s) of LEDs arranged in zones, wherein each zone of LEDs is separately controllable. In some embodiments, the energy source 138 may be a conventional lamp augmented with LEDs strewn about areas of the lamp head that had previously not been a light-emitting surface, increasing usage of the heat source surface area.

In FIG. 1, energy sources 138 are shown above the substrate 101 for heating an upper surface of the substrate 101, and on each side of the substrate 101 (which may be used, for example, to heat edge ring 126 which contacts substrate 101). Alternatively, energy sources 138 may be configured provide pulsed and/or continuous energy in process chamber 100. In some embodiments, energy source 138 may be used to heat the back side of the substrate 101, for example, such as by being disposed below the substrate 101, or by directing the radiation to the back side of the substrate 101. Each energy source 138 is coupled to one or more power sources 170 which may be coupled to controller 140 to separately control each energy source 138. The temperatures at localized regions of the substrate 101 are measured by a plurality of temperature probe assemblies, such as 120, that passes through a through a hole that extends from the back side of the base 116 through the top of a reflector plate 102. However, since the monochromatic properties of LEDs will not cause pyrometer interference, in some embodiments, temperature measurements may advantageously be obtained via pyrometers disposed anywhere in the chamber. The temperature probe assemblies 120 transmit sampled light from the reflecting cavity 118 to a pyrometer 128. The pyrometer 128 is connected to controller 140 which controls the power supplied to the energy sources 138 (e.g., a lamp head) in response to a measured temperature. The energy sources 138 may be divided into multiple zones. The zones can be individually adjusted by the controller to allow controlled radiative heating of different areas of the substrate 101. In other embodiments, each light (LED or conventional light source) in energy sources 138 may be separately controlled to facilitate even finer control of the radiative heating.

In some embodiments, a cooling mechanism 150 may be used to cool the energy sources 138. Some exemplary cooling mechanisms 150 may include, for example, the use of heat sinks, heat exchange fluid cooling channels or fins, band pass filters, etc. coupled to (as discussed below) the energy sources 138. In some embodiments, the substrate on which the light sources are mounted or grown on may itself be a heat sink used for cooling. In other embodiments, energy sources 138 may be cooled by a gas or liquid circulated around or proximate to the energy sources 138.

A substrate support 124 included in chamber 100 may include parts of a process kit 125 which may be adapted to work with various embodiments of substrate supports and/or process chambers. For example, the process kit 125 may include elements of the substrate support 124, such as edge ring 126 and an edge ring support 127.

During processing, the substrate 101 is disposed on the substrate support 124. The energy source 138 is a source of radiation (e.g., heat) and, in operation, generates a pre-determined temperature distribution across the substrate 101. In embodiments, where the heat source includes LEDs (as shown in FIG. 2), the energy source 138 may provide energy in wavelengths ranging from ultraviolet wavelengths to infrared wavelengths (e.g., about 100 nanometers (nm) to about 2000 nanometers (nm)). In some embodiments energy source 138 (e.g., LED array) may provide energy in the microwave wavelength range. The energy source 138 provides heat radiation that is absorbed by the substrate 101. Although some of the heat radiation produced by an LED source may be reflected, substantially all of the heat radiation that is not reflected is absorbed by the target component being heated. In embodiments described herein, the substrate 101 may bow, for example up to about 5 mm, during heating. Thus, in some embodiments, the LED energy source 138 should be placed just far enough away to avoid contact if the substrate 101 bows, but close enough to provide the necessary uniform heat energy to the target substrate. In some embodiments, the LED energy source 138 may be bowed or shaped to compensate for the target substrate deformation.

In the exemplary processing chamber 100 described above, energy source 138 may be used to illuminate and heat the surface of a substrate to process the near surface region of the substrate. LED light sources offer a variety of advantages including higher efficiency and more rapid response times. Pulse widths are selectable and can range to less than a millisecond to more than a second.

In some embodiments, the LED energy source 138 may be used in conjunction with processing chambers to form films, treat dopants, change process gases (e.g., break bonds), and reorder the substrate itself. Additional high temperature substrate processing may benefit from LED heating as even higher output intensities become available. LEDs offer advantages when used to process the near surface region of a substrate. LEDs last a long time and allow the output intensity to be chosen independent from the wavelength(s) of the output illumination. Light emitting diodes (LEDs) may consist of gallium nitride, aluminum nitride, combinations thereof or other III-V materials grown on a substrate constructed to emit light close to one or more wavelengths determined by the bandgap of III-V materials in the active region. A phosphor may also be used to convert an emitted wavelength to a longer wavelength, reducing the energy of an emitted wavelength. It will be understood that the solid state sources described herein and depicted in the remaining figures may employ a phosphor in order to enhance absorption or enhance a chemical reaction.

Depending on the chemistries involved, illuminating a surface in the presence of gas precursor can enhance the rate of chemical reactions by thermal or other means. For example, the light may excite gas phase molecules, adsorbed molecules, or even excite the substrate to promote a chemical reaction on the surface. The wavelength of the LED may be selected to promote desirable film processes by, for example, choosing a wavelength which is resonant with a molecular electronic transition in order to enhance a reaction rate. The wavelength may also be chosen to enhance absorption of the radiation by the substrate, thereby heating the substrate more efficiently.

In some embodiments, each energy source 138 in FIG. 1 may include one large array of LEDs. However, depending on the heat energy and area to be heated, one large array of LEDs may require more power than can safely be provided without damage to the LEDs and associated circuitry. The inventors have observed that by modularizing LEDS into a plurality of smaller LED arrays, the smaller LED arrays can be more easily handled, manufactured, and powered. In addition, a plurality of smaller arrays of LEDs may also help in the event of LED failure. For example, in some embodiments, if one led fails and becomes an open circuit, then only the heat emitted from the small LED array is lost. If one large array of LEDs is used, then one LED failure may cause all processing to stop. In some embodiments, each of the plurality of smaller LED arrays can have different modules with different wavelengths. In some embodiments, each LED array can be removed and replaced with another LED array with different wavelengths.

FIG. 2 shows at least one exemplary embodiment of an energy source 138 that includes a plurality of LED arrays 204 disposed on a LED substrate 202 for thermally processing other substrates and/or heating various processing chamber components disposed in the processing chamber.

In some embodiments, energy source 138 may illustratively be between 100 mm and 480 mm in length and between 100 mm and 480 mm in width. In addition, various size energy sources 138 may be used as required or desired in any particular application. In some embodiments, each LED array 204 may be about 20 mm by about 20 mm square, although other size LED arrays 204 may be used. Each LED array 204 may contain between about 50 and about 500 LEDs 206 (e.g., 384 LEDs as shown in FIG. 2B). LEDs 206 may be spaced between about 0.1 mm and about 0.5 mm apart. LED arrays 204 may be spaced between about 0.5 mm and about 4 mm apart. Each LED 206 in LED arrays 204 may emit light and heat energy from one or more exposed surfaces. In some embodiments, all exposed surfaces of each LED 206 may emit light and heat energy. In some embodiments, each LED may be about 0.7 mm by about 0.7 mm square and about 0.3 mm in height, although other size LED 206 may be used. LEDs 206 may emit wavelengths in the Ultra Violet (UV) (200-400 nm), visible light (400-700 nm) and near infrared (700-1000 nm) wavelength ranges. The optical output of LEDs 204 are on the order of 1 W/mm̂2 or greater, which corresponds to an intensity of 1e6 W/m̂2 with sufficiently high packing densities. With sufficiently high packing densities of LEDs 206 over a given area, the LED arrays 204 advantageously provide the ability to achieve rapid thermal processing. In addition, LEDs can also be operated at a lower intensity as needed for other processes that do not require high power. The wide range of available wavelengths for LEDs advantageously enable wavelength specific, high intensity sources for industrial applications. Multi-wavelength capability can be realized in a single LED array 204 or across multiple LED arrays 204 in a system. Due to the high efficiency of LEDs (60-80% efficiency), less energy is converted to waste heat which can reduce thermal management issues.

In addition, LEDs 206 and LED arrays 204 have faster on-off switching times than incandescent lamps. In some embodiments, the LEDs have on-off switching times on the order of nanoseconds versus hundreds for milliseconds for incandescent lamps. Specifically, in some embodiments, the LEDs have a switch-on time from about 0.5 nanoseconds to about 10 nanoseconds and a switch-off time from about 0.5 nanoseconds to about 10 nanoseconds. Faster on-off switching times enables shorter thermal exposures. The use of small form factor LEDs as described above makes it possible to design conformal high intensity illumination systems at a lower cost of ownership, longer operating lifetime (˜100 k hours) and in the case of UV LEDs, an environmentally sensitive alternative to toxic mercury vapor based lamps.

In some embodiments, the LED array 204 can be individual LED chips 206 with different wavelengths, or the LED array 204 can be a collection of LED lamps with different wavelengths. The LEDs can be multiplexed/rasterized such that certain LEDs with certain wavelengths are activated at one time. For example, at time 1t, only λ1 LEDs are active, at time 2t only λ2 LEDs are active, etc. Thus, the LEDs in LED array 204 can be grouped and separately controlled by a controller (e.g., controller 140).

In some embodiments, the reflectors 208, 210 are configured to reflect the light and heat energy emitted from the LED towards the desired target (e.g., wafer substrate, or other process chamber component, etc.). In the case of LASERS, the reflectors 208, 210 could direct the light off of the LASER beams' axis to heat a wafer substrate or desired process chamber component. The reflectors 208 and 210 may be angled to reflect radiated LED light in a desired direction. In some embodiments, the angles of the incline of the reflector surfaces from the LED substrate 202 surface is between about 45 to 55 degrees from an axis of the LED extending in a direction toward where light energy is desired (e.g., for a planar array of LEDs, the axis may be perpendicular to the planar array), however, any angle which maximizes the angle and desired length of the reflector based on the space available between two neighboring LEDs 206, or LED arrays 204, may be used. In other embodiments, the surfaces of the reflectors 208, 210 may be perpendicular to the surface of the LED substrate 202. Still, in other embodiments, the surface of the LEDs 206 may be angled instead of, or in addition to, the surface of the reflector. In some embodiments, the height of the reflectors 208, 210 is at least the same height as the height of the LEDs 206, but may be higher or lower than the LEDs 206 as required.

In some embodiments each LED 206 may be individually mounted on LED substrate 202. Each LED 206 may be mounted to the substrate via eutectic bonding, including wire-bond-free direct attach LEDs. To direct attach LEDs to a substrate, a flux is first disposed on the substrate surface to which the LEDs will be attached. The LEDs are then disposed over this surface. The LEDs and the surface are then heated with a certain heating profile. An amount of solder disposed on the bottom of the LED will melt with help of the flux, and will attach the LED to the fluxed surface. In some embodiments, each LED 206 may be grown on LED substrate 202. The LEDs 206 may be individually grown, grown in groups/sections, or grown all together at the same time. In some embodiments, the LED substrate 202 that LEDs 206 are grown on may be an n-type substrate, with an electrode (e.g., 214) attached to the p-type layer 240 deposited on its surface. Silicon substrates or sapphire substrates may be used as well. The substrate can be any material that is thin enough, or has a high thermal conductivity, such that it is able to dissipate heat from the LEDs quickly while also providing electrical isolation of the LEDs from the rest of the system. This can be done by using an electrically isolating material. LEDs can be grown on any material where the lattice structure of the substrate can be made to match the lattice structure of the LED material through, but not limited to, direct deposition, application of a buffer layer, and/or any type of stress relaxation. In some exemplary embodiments, the substrate can be ceramic. In some embodiments, islands of non-substrate material/chemistries may be grown or included in the substrate to help facilitate LED growth.

In some embodiments, the LEDs 206 in LED arrays 204 are connected in series. In some embodiments, the LEDs 206 are disposed on LED substrate 202 in a recursive pattern on a first surface of the substrate 202. The recursive pattern maximizes the use of the available surface area of the first surface of the substrate 202. In some embodiments, the recursive pattern is a serpentine structure including a plurality of rows of LEDs 206, such that each row of LEDs 206 is electrically coupled to at least one other row of LEDs 206 as shown in FIG. 3. FIG. 3 is a schematic top view of a disk shaped LED array 204 having a circular cross section and depicts embodiments of an LED array 204 where LEDs are direct attach LEDs connected in series, in a recursive pattern on a circular cross section substrate 202. Each column of LED 206 is connected to another column of LEDs 206 via electrical connections 318. In FIG. 3, power source contact pad 310 is coupled to power source 314, and ground contact pad 312 is coupled to ground 316.

Due to the high packing density of the LED arrays 204 described in embodiments of the present invention, some embodiments may require the use of a cooling mechanism 150 for heat dissipation and thermal management as described below with respect to FIGS. 4-7.

FIG. 4 is a schematic cross sectional side view of at least one embodiment of a cooling mechanism 150 used to cool an LED array 204 in a process chamber. The cooling mechanism 150 in embodiments consistent with FIG. 4 is a window with a band pass filter 402. The use of a band pass filter 402 involves placing a transparent window sheet with a band pass filter between the LED array 204 and the device to be heated (e.g., substrate 101). The window is usually quartz but can be other types of transparent material to adjust the band pass properties in conjunction with the filter. In some embodiments, the window may be a stack of windows coupled together. The band pass filter itself can consist of single or multiple layers of dielectric films designed to pass a certain band of wavelengths. Other methods of creating band pass filters may be used.

In some embodiments, the band pass filter 402 may reduce the heat built up of the LED array 204 by reducing/filtering the amount of radiation reflected and re-emitted back to the LED array 204. Specifically, a band pass filter 402 advantageously allows for a narrow range of wavelengths pass for a specific process as desired. For example, in some embodiments, a specific range of LED wavelengths may be required for purposes of film modification, film cure specific wavelength, and the like. The band pass filter 402 will filter out all other wavelengths emitted from the LEDs 206 and pass only the wavelengths desired for the process. For example, with respect to FIG. 4, all wavelengths emitted from LEDs 206 are filtered by band pass filter 402 except for the wavelength of transmitted light 410. Transmitted light 410 may be used to heat substrate 101 in a process chamber. The reflected radiation 412 reflects off of the substrate 101 and back towards the LED array 204. In addition, as substrate 101 heats up due to transmitted light 410, the substrate re-emits heat radiation 414, at least some of which may be directed back towards the LED array 204. This re-reflected radiation 416 is then directed back towards the substrate 101. Although discussed in terms of LED arrays, in some embodiments the band pass filter 402 may be similarly used with respect to conventional lamps (tungsten-halogen, mercury vapor, arc discharge) or electrical heating elements.

When filtering/reflecting various wavelengths of light, the band pass filter 402 may get hot. In addition, additional cooling of the LEDs may be required. Thus, in some embodiments, the use of low temperature liquid immersion cooling may be used as shown and discussed with respect to FIGS. 5A and 5B. In embodiments consistent with FIG. 5A, the LEDs 206 are immersed in a low temperature fluid 502 which is flowed over the LEDs 206 in a cooling channel 506 to assist in heat removal of the LEDs 206 and the band pass filter 402. In some embodiments, a band pass filter may not be present and only a window for containing the low temperature fluid 502 may be used. In some embodiments, the LEDs 206 are attached to finned heat sinks 504 and immersed into a low temperature circulating fluid 502 to maximize the heat extraction as shown in FIG. 5B. In some embodiments, only the LEDs 206 and a portion of the finned heat sinks 504 are immersed in the coolant and not the electrical connections on the LED substrate 202.

In some embodiments, the low temperature fluid could be ethylene glycol, alcohol, water, de-ionized water, oil or any combination thereof. In some embodiments, the low temperature circulating fluid 502 is a high resistivity coolant that doesn't react with the LEDs. In some embodiments, the liquid temperature can be less than 0 C, e.g. −40 C, depending on the coolant used.

The use of low temperature circulating fluid 502 advantageously reduces the overall thermal load on the LEDs 206, improving the LED array 204 performance and system lifetime. In the case of temperature sensitive LED light sources, liquid cooling may mitigate or solve issues related to keeping LEDs cool enough for over driving to extract more intensity.

In some embodiments, the cooling mechanism 150 may be a finned heat sink structure 602 with a coolant 610 flowed therethrough, as shown in FIG. 6. The finned heat sink structure 602 includes a plurality of fins 604 coupled between two plates or blocks 606 (e.g., a base plate and a top plate). In some embodiments, the blocks may be metallic and made of copper or aluminum which may be selected based on thermal conductivity performance require. The finned heat sink structure 602 may be coupled to a backside (opposite the LED surface) LED substrate 202 to remove heat from LED array 204. In some embodiments, the plurality of fins 604 could be further modified to increase the amount of surface area by adding corrugations, sinusoidal shape or dimples as shown in FIGS. 7A, 7B and 7C, respectively. In some embodiments, the fins 604 may be from about 0.1 mm to about 5.0 mm wide. The gaps between each fin 604 may be about 0.1 mm to about 2 mm wide. The fins may be grouped in columns as shown in FIG. 6 or may be arranged as a series of continuous fins extending from coolant inlets to coolant outlets.

Referring back to FIG. 6, in some embodiments, the finned heat sink structure 602 may be larger than the substrate to accommodate light dispersion at the edges and edge support structures (i.e., edge losses). For example, in some embodiments, the finned heat sink structure 602 may be about 50 mm to about 100 mm larger in a radial direction over the size of the substrate. Thus, in some embodiments, the finned heat sink structure 602 may between about 250 mm and about 550 mm square to accommodate a large area of high density LED arrays that could be used for delivering energy to 200, 300 and 450 mm substrates. In some embodiments, the total thickness of the finned heat sink structure may be no more than 2 cm thick.

A coolant 610 may be delivered (e.g., from a coolant reservoir by a pump) at up to 60 gallons per minute through the finned heat sink structure 602. Depending on the fin structure and heat removal required, the flow rate may be reasonably high in order to ensure turbulent conditions at the heat sink/liquid interface which will reduce the boundary layer of the fluids and overall thermal resistance. For lesser heat removal requirements, the flow rate may be lower to provide a more laminar flow, reduce the pressure drop and required fluid inlet pressure. The coolant 610 could be any liquid. In some embodiments, water is used due to its high heat capacity, compatibility with most materials, and low cost. In some embodiments, other liquids such as antifreeze (e.g. any combination of water, ethylene glycol, diethylene glycol, propylene glycol, etc.), dielectric fluids (e.g. oil, silicone oil, mineral oil, fluorocarbon oil), or liquid gases (O2, N2, H2, CO2 etc) may be used. Embodiments of the finned heat sink structure 602 described herein advantageously improve cooling efficiency and can help manage the cyclical fatigue and cracking associated with system elements thermally expanding.

While the foregoing is directed to embodiments of the present invention, other and further embodiments of the invention may be devised without departing from the basic scope thereof.

1. An apparatus for providing pulsed or continuous energy in a process chamber, the apparatus comprising:
a process chamber comprising a chamber body;
a solid state light source array, having a plurality of solid state light sources disposed on a first substrate, to provide pulsed or continuous energy in the process chamber; and
a cooling mechanism including a band pass filter to reduce an amount of reflected light from heating the solid state source array.

2. The apparatus of claim 1, wherein each of the plurality of solid state light sources are at least one of light emitting diodes (LEDs) or Laser Diodes.

3. The apparatus of claim 1, wherein the band pass filter is at least one of embedded in a transparent window or coated onto the transparent window, and wherein the transparent window is disposed over the plurality of solid state light sources.

4. The apparatus of claim 3, wherein the band pass filter and the window encapsulate the plurality of solid state sources.

5. The apparatus of claim 3, wherein the window is comprised of transparent quartz.

6. The apparatus of claim 3, wherein one or more band pass filters are coated onto at least one side of the transparent window.

7. The apparatus of claim 1, wherein the band pass filter is comprised of multiple layers of dielectric films capable of transmitting selected bands of wavelengths of light produced by the solid state light source array.

8. The apparatus of claim 1, wherein the band pass filter is configured to reflect filter at least some wavelengths of light directed towards the solid state source array.

9. The apparatus of claim 1, wherein the cooling mechanism further includes a cooling channel disposed between the plurality of solid state light sources and the band pass filter configured to flow a coolant over the plurality of solid state light sources.

10. The apparatus of claim 9, wherein each of the plurality of solid state light sources is coupled to a heat sink base, and wherein the cooling channel is configured to flow the coolant over the plurality of solid state light sources and at least a portion of the heat sink base.

11. An apparatus for providing pulsed or continuous energy in a process chamber, the apparatus comprising:
a process chamber comprising a chamber body;
a solid state light source array, having a plurality of solid state light sources, disposed on a first substrate, to provide pulsed or continuous energy to the process chamber; and
a cooling mechanism including a transparent window disposed over the solid state light source array, the transparent window at least partially defining a cooling channel disposed between the plurality of solid state light sources and the transparent window to flow a coolant over the plurality of solid state light sources.

12. The apparatus of claim 11, wherein each of the plurality of solid state light sources are at least one of light emitting diodes (LEDs) or Laser Diodes.

13. The apparatus of claim 11, wherein each of the plurality of solid state light sources is coupled to a heat sink base, and wherein the cooling channel is configured to flow the coolant over the plurality of solid state light sources and at least a portion of the heat sink base.

14. The apparatus of claim 11, wherein the coolant is a high resistivity coolant that does not react with the plurality of solid state light sources.

15. An apparatus for providing pulsed or continuous energy in a process chamber, the apparatus comprising:
a process chamber comprising a chamber body;
a solid state light source array, having a plurality of solid state light sources, disposed on a first surface of a substrate, to provide pulsed or continuous energy to the process chamber; and
a cooling mechanism coupled to a second surface of the substrate to remove heat from the solid state light source array, the cooling mechanism including a base plate, a top plate, and a plurality of fins disposed between the base plate and the top plate.

16. The apparatus of claim 15, wherein each of the plurality of solid state light sources are light emitting diodes (LEDs).

17. The apparatus of claim 15, wherein a plurality of cooling channels are formed by gaps between each of the plurality of fins.

18. The apparatus of claim 17, wherein the cooling mechanism is configured to flow a coolant through the plurality of cooling channels and about the plurality of fins disposed between the base plate and the top plate.

19. The apparatus of claim 17, wherein the cooling channels are about 0.5 mm and about 2.0 mm wide.

20. The apparatus of claim 15, wherein each of the fins are include at least one of corrugations or dimples to increase an amount of surface area in contact with a coolant that flows through the plurality of fins.
